(19) United States
(12) Patent Application Publication
(10) Pub. No.: US 2006/0249369 A1
(43) Pub. Date: Nov. 9, 2006

(54) Process for physical vapor deposition of a chalcogenide material layer and chamber for physical vapor deposition of a chalcogenide material layer of a phase change memory device

(75) Inventors: Maria Santina Marangon, Merate (IT); Paola Besana, Bareggio (IT); Raimondo Cecchini, Cagallo Di Montecalvo In Foglia (IT); Mauro Tresoldi, Carugate (IT)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics S.r.l., Agrate Brianza (IT)

(21) Appl. No.: 11/398,849

(22) Filed: Apr. 5, 2006

(30) Foreign Application Priority Data
Mar. 31, 2006 (EP) 06112075.4
Apr. 8, 2005 (EP) 05102812.4

(51) Int. Cl. C23C 14/32; C23C 14/00

(52) U.S. Cl. 204/192.1; 204/298.02

(57) ABSTRACT

A method for depositing a chalcogenide layer in a phase change memory, whereby a chalcogenide layer is deposited by physical vapor deposition in a deposition chamber, having a collimator. The collimator is formed by a holed disk arranged in a deposition area delimited by the chamber walls and the chamber cover. The target is biased by a pulsed voltage to avoid charging and arching. The method is used to manufacture a phase change memory cell, whereby a resistive heater element is formed in a dielectric layer, a mold layer is formed over the dielectric layer; an aperture is formed in the mold layer over the resistive heater element; a chalcogenide layer is conformally deposited in the aperture to define a phase change portion; and a select element is formed in electrical contact with the phase change portion.

### BACKGROUND OF THE INVENTION

1. Field of the Invention

The present invention relates to a process for physical vapor deposition of a chalcogenide material layer and a chamber for physical vapor deposition of a chalcogenide material layer of a phase change memory device.

2. Description of the Related Art

As is known, phase change memory (PCM) elements exploit the characteristics of materials which have the property of changing between two phases having distinct electrical characteristics. For example, these materials may change from an amorphous phase, which is disorderly, to a crystalline or polycrystalline phase, which is orderly, and the two phases are associated to considerably different resistivities.

At present, alloys of group VI of the periodic table, such as Te or Se, referred to as chalcogenides or chalcogenic materials, can advantageously be used in phase change cells. The chalcogenide that currently offers the most promise is formed by a Ge, Sb and Te alloy (Ge₂Sb₂Te₅), also called GST, which is currently widely used for storing information in overwritable disks.

In chalcogenides, the resistivity varies by two or more magnitude orders when the material passes from the amorphous phase (more resistive) to the crystalline phase (more conductive) and vice versa.

Phase change can be obtained by locally increasing the temperature. Below 150° C., both phases are stable. Starting from an amorphous state, and raising the temperature above 200° C., there is a rapid nucleation of the crystallites and, if the material is kept at the crystallization temperature for a sufficiently long time, it undergoes a phase change and becomes crystalline. To bring the chalcogenide back to the amorphous state it is necessary to raise the temperature above the melting temperature (approximately 600° C.) and then rapidly cool off the chalcogenide.

Memory devices exploiting the properties of phase change material (also called phase change memory devices) have been already proposed.

In a phase change memory including chalcogenic elements as a storage element, memory cells form an array and are arranged in rows and columns, as shown in FIG. 1. The memory array 1 of FIG. 1 comprises a plurality of memory cells 2, each formed by a memory element 3 of the phase change type and a selection element 4. The memory cells 2 are interposed at cross-points of columns 5 (also called bit lines) and rows 6 (also called word lines).

The basic structure of a phase-change memory element 3 is shown in FIG. 2 and comprises essentially a resistive element 7 (heater) and a programmable element 8. The programmable element 8 is made of a chalcogenide and is normally in the crystalline state. One part of the programmable element 8 is in direct contact with the resistive element 7 and forms a phase-change portion 9.

The composition of chalcogenides suitable for the use in a phase change memory device and a possible structure of a phase change element is disclosed in a number of documents (see, e.g., U.S. Pat. No. 5,825,046).

The selection element 4 may be implemented by any switching device. In one embodiment, the selection element 4 is a PN diode, a bipolar junction transistor or a MOS transistor formed in the substrate of the chip integrating the memory device 1.

In another embodiment, the selection element 4 is an ovonic threshold switch that is made of a chalcogenide alloy that does not exhibit an amorphous to crystalline phase change and which undergoes rapid, electric field-initiated change in electrical conductivity that persists only so long as a holding voltage is present.

In both cases, selection element 4 operates as a switch that is either “off” or “on” depending on control quantities applied thereto.

Processes for manufacturing PCM cells and arrays have been already proposed; a detailed description of a known manufacturing process having a bipolar selection element may be found in. U.S. Published Application No. 2003/0219924. Another process for manufacturing a phase change memory array in Cu-damascene technology is disclosed in U.S. Published Application No. 2005/0064606, in the name of STMicroelectronics, S.r.l., the assignee of the instant application.

Considering for example the process disclosed in U.S. 2003/0219924 and U.S. 2005/0064606, starting from a wafer 10 having a substrate 11 of P-type, first insulation regions 12, base regions 13 of N-type, base contact regions 14 of N⁺-type, emitter regions 15 of P⁺-type are formed (FIG. 3). A first dielectric layer 18 covers the substrate 11, base contacts 19b and emitter contacts 19a extend through the dielectric layer 18 and are in electrical contact with the base contact regions 14 and the emitter regions 15, respectively. The base regions 13 and emitter regions 15 form the selection element 4 of FIG. 1.

Next, FIG. 4, a second dielectric layer 20 is deposited, and openings 21 are formed in the second dielectric layer 20 above the emitter contact 19a. The openings 21 have substantially rectangular or oval shape. A heating layer 22, for example of TiSiN, TiAlN or TiSiC, is deposited and conformally coats the walls and bottom of the openings 21. The openings 21 are then completely filled with dielectric material 23. The heating layer 22 and the dielectric material 23 are removed outside the openings 21 by CMP (“Chemical Mechanical Polishing”) and the surface of the wafer 10 is planarized. The remaining portions of the heating layer 22 form a cup-shaped region 22.

Subsequently, a mold layer 27, preferably of silicon nitride having a thickness of 60-90 nm, and an adhesion layer 28, for instance Ti or Si with a thickness of 5 nm, are deposited. Later, layers 27 and 28 are etched so as to obtain a microtrench 31, which crosses the cup shaped region 22 at areas placed before and behind the plane of the drawing. Etching is carried out so that microtrench 31 has inclined walls. For example, etching may be a combined chemical and physical plasma, as disclosed in detail in U.S. 2005/0064606.

Then, a chalcogenic layer 35, for example of Ge₂Sb₂Te₅ (also called GST layer) with a thickness of 60 nm, is deposited conformally. A thin portion 35a of the chalcogenic layer 35 fills the microtrench 31 and forms, at the intersection with the cup-shaped region 22, the phase change region 7 of FIG. 2. On top of the chalcogenic layer 35 a barrier layer 37, for example of Ti/TiN, and a metal layer 38, for example of AlCu, are deposited. The stack formed by the metal layer 38, barrier layer 37, chalcogenic layer 35, and adhesion layer 28 is defined using a same mask to form a bit line 40; a third dielectric layer 42 is deposited, planarized, for example by CMP, and then opened above the base contacts 19b and above a portion (not shown) of the bit line 40. The openings thus formed are filled with tungsten to form top contacts 43 in order to prolong upwards the base contacts 19b. Then standard steps are performed for forming the connection lines for connection to the base contacts 19b and to the bits lines 40, and the final structure of FIG. 5 is thus obtained.

One critical step in the above process is the deposition of the GST or chalcogenic layer 35. In fact, a common deposition technique, like conventional sputtering, is difficult to be used for depositing layers of calcogenides, since the sputtering process could stop after a while or arcs could occur.

Another problem resides in the fact that, for a proper functioning of the memory device, it is necessary that the GST layer be deposited conformally, in particular, that a sufficiently thick, uniform GST layer 35 is deposited on the bottom of the trench 31 in all conditions; furthermore, it is important that no void areas are formed.

However, the above conditions are difficult to obtain in case of a GST layer 35 having a high thickness (e.g., greater than 120 nm) and/or when the microtrench 31 has a high aspect ratio (that is, high depth compared with the width thereof.

In particular, tests carried out by the applicant have shown that while the conformality of GST layer 35 is quite good for thin films (of about 60 nm) and low-aspect ratio microtrenches 31, the increase in thickness of the GST film 35 being deposited causes an increase of the deposition thickness on the vertical walls of the microtrench, in particular on the upper edges thereof. As a result, for thick deposited layers and/or for high aspect ratio microtrenches 31 (in particular, in case of trenches having a higher depth than width), the formation of keyholes (that is, void regions where no GST material is present) has been observed.

On the other hand, the use of thick GST films and/or high aspect ratio microtrenches 31 is required for modulating the current flowing through the memory device and/or to obtain small contact areas between the heater and the phase change regions of GST.

Test carried out by the applicant have however shown that changing deposition parameters (e.g., increasing the deposition temperature) does not allow to solve the above problem.

### BRIEF SUMMARY OF THE INVENTION

In one embodiment, the present invention provides a method for depositing high conformal phase change layers also in case of thick layers and/or trenches or holes having a high aspect ratio.

In one embodiment, the present invention provides a method for depositing a chalcogenide material layer in a phase change memory comprising: providing a wafer in a deposition chamber; and depositing by pulsed sputtering, through a collimator, the chalcogenide layer by physical vapor deposition on the wafer in the deposition chamber.

In another embodiment, the present invention provides a deposition chamber comprising: a wall surrounding a deposition area and the deposition area being closed by a cover; a holder for a wafer extending in the deposition area; a collimator in the deposition area between the cover and the holder; and a sputter target over the collimator, the sputter target being connected to a DC pulsing power supply.

The invention derives from the understanding that the interruption of the sputtering process or occurrence of arcing (e.g., a low impedance that appears at the output of the power supply) are due to the fact that, during sputtering, the chalcogenic material acts like an insulator. In fact, sputtering is caused when a negative voltage is applied to a target. Thus, the target attracts positive ions from the plasma which knocks loose a target ion and capture an electron from the target, becoming neutral. In the case of the chalcogenic material, however, after a positive ion has caused the sputtering of the ion, the positive charge attracts an electron on the target surface or back plate and remains firmly connected thereto at the capture place. Thus, a sort of capacitor is formed, wherein one plate is the metal target, the insulator is the chalcogenic material to be sputtered, and the other plate is the surface of the calcogenic material. In the course of the sputtering process, ions arriving at the target surface continue charging the capacitor, reducing the voltage between the target and the plasma. In the end, sputtering could stop. Furthermore, the film, if unable to withstand the electric field created by charging, can brake down and initiate an arc. Arcs can generate particulates that can be ejected onto the substrate or can remain on the target and become a source for further arcing.

Furthermore, applicant has noted that the low conformality in the deposition of a GST layer is caused by the fact that the GST or chalcogenide ions sputtered by a target in a conventional deposition chamber and having a wide angular distribution are more likely to deposit in the upper part of the vertical or slightly sloped walls of the trench or hole than in the lower part of the walls and thus cause the deposited film to grow preferentially in the upper parts of the walls. As deposition proceeds, the more rapidly increasing portions of the deposited film at the upper corners reduce progressively the chances that the sputtered ions reach the bottom portion of the walls, preventing in the end the passage of the sputtered ions to the bottom of the hole and thus the filling thereof; thereby the finished device may present keyholes.

This situation is depicted in FIG. 6, showing a schematic, exaggerated representation of the deposition of GST layer 35 in microtrench 31 for different thicknesses of the GST layer 35.

Thus, by altering the angular distribution of the sputtered ions and, more specifically, causing only collimated ions having a desired direction to reach the deposition area, it is possible to obtain a smoother and more uniform growth in all the portions of the hole.

### BRIEF DESCRIPTION OF THE SEVERAL VIEWS OF THE DRAWINGS

For the understanding of the present invention, a preferred embodiment is now described, purely as a non-limitative example, with reference to the enclosed drawings, wherein:

FIG. 1 is a schematic diagram illustrating the scheme of a phase change memory;

FIG. 2 shows the basic structure of a known chalcogenic element;

FIGS. 3-5 are cross-sections through a semiconductor wafer in successive manufacturing steps of a phase change memory device;

FIG. 6 is a schematic illustration of the irregular growth of an GST film according to a conventional method;

FIG. 7 is a schematic illustration of the regular growth of an GST film according to the invention;

FIG. 8 shows a cross-section of a deposition chamber according to an embodiment of the invention;

FIG. 9 shows a top view of a collimator mounted in the deposition chamber of FIG. 8; and

FIG. 10 is a system depiction of one embodiment of the present invention.

### DETAILED DESCRIPTION OF THE INVENTION

According to one aspect of the invention, the deposition chamber is modified so as to transform the flux of ions sputtered by the target and having a wide angular distribution, into a “collimated” beam or flux that is allowed to hit the wafer surface. Here “collimated” beam or flux refers to a group of ions having mainly a desired direction. The “collimation” of the hitting ions is here obtained by preventing ions directed along undesired direction to reach the wafer surface through a screen or “collimator”. A collimator causes ions arriving at the collimator with a sloped direction to be more likely intercepted by the collimator.

Furthermore, a pulsed-type sputtering technique is used, so as to avoid the above described problems of charging and arcing. In particular, during sputtering, the voltage applied to the target is periodically reversed, e.g., to a tenth or a twentieth of the operating target voltage. The voltage reversal attracts electrons to the target, discharging any ions remaining on the surface thereof, but does not affect the plasma, by virtue of its low value. When the voltage is reversed back to the negative value, sputtering of the chalcogenide is resumed.

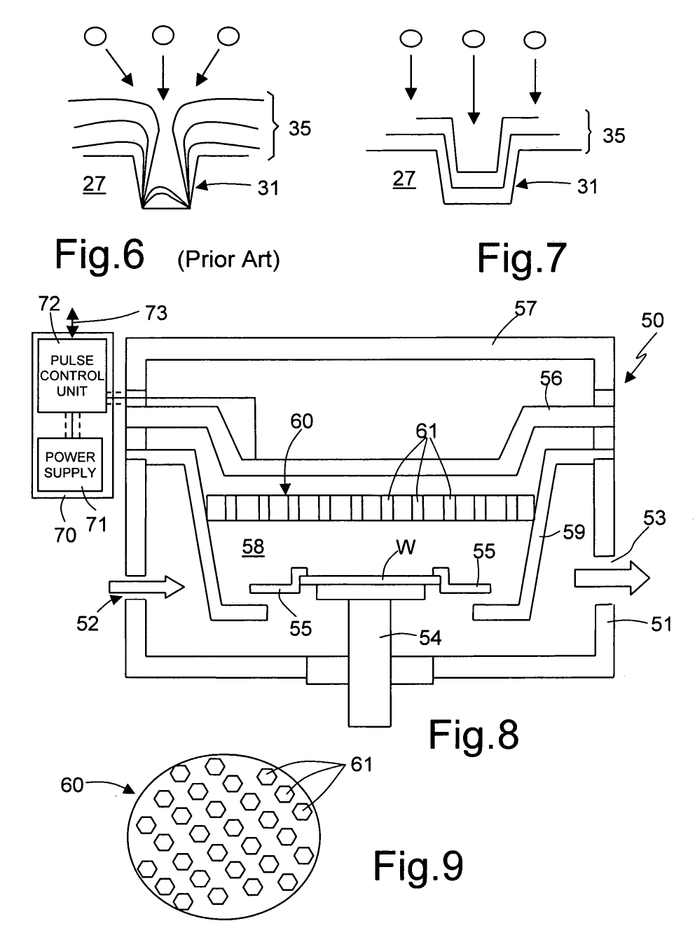

FIG. 7 shows schematically the uniform deposition observed for different thickness GST films 35 using collimated ions, to be compared with the situation of the conventional method of FIG. 6.

A deposition chamber according to an embodiment of the invention is represented in FIG. 8, showing only the components essential to the comprehension of the invention.

Chamber 50 has an external wall 51 with a gas inlet 52 and a gas outlet 53. Gas outlet 53 is connected to a pump, not shown. The wall 51 is upwardly closed by an upper cover 57. A holder 54 supports a wafer W, held by means of clamps 55. A target 56 extends in the chamber 50 and a shield 59 delimits, with holder 54 and the target 56, a deposition area 58 within the chamber 50.

The target 56 is connected to a DC pulsing plasma power supply 70 including a power supply unit 71 and a pulse control unit 72. The power supply unit 71 generates a high voltage, which is periodically reversed by the pulse control unit 72. The output of the pulse control unit 72 is connected directly to the target 56. The pulse control unit 72 has also an input/output 73 for connection to user controls. An example of a DC pulsing plasma power supply 70 is described in U.S. Pat. No. 5,427,669, and causes a pulsed sputtering of ions and thus sputtering of chalcogenides. For example, the voltage applied to the target 56 may be reversed with a frequency of 20 to 100 kHz, the applied direct voltage is in the range 200 to 600 Volts and the reversed voltage is in the range 20 to 120 Volts.

A collimator 60 extends in the deposition area 58. As better shown in FIG. 9, the collimator 60 is a holed disk having a number of holes 61 for preferentially allowing ions having a direction perpendicular to the collimator 60 to pass through and hit the wafer W. The geometrical parameters of the collimator 60, such as the aspect ratio of the holes 61 and the distance of collimator 60 from the target 56, influence the number of the ions passing through the collimator and having a direction different from the perpendicular one (angular distribution width) as discussed for the deposition of Ti in “Theoretical and practical aspects of collimated sputtering” S. K. Dew, J. Appl. Phys. 76(8), 15 Oct. 1994.

The use of a pulsed type sputtering, together with the use of a collimator 60 in the chamber 50, allows a high conformality deposition of the GST layer 35 in the trench 31 to be achieved.

Tests performed by the applicant have confirmed that the use of a pulsed sputtering and of the collimator 60 allows the obtainment of a GST layer 35 having a very good bottom coverage (ratio between the GST thickness at the bottom of the trench 31 and on flat surface).

In particular, from test samples prepared by the applicant, a bottom coverage of 67% has been observed in standard non-collimated samples, and, by comparison, a 93% bottom coverage has been observed in the novel collimated samples.

In other test samples, wherein a metal layer was deposited on top of the GST/cap layer, voids have been observed in a standard process sample, while the deposition is conformal in collimated samples.

As demonstrated by the test samples, the use of the present process allows obtainment of a high conformality of the GST layer in PCM cells, improves the bottom coverage and morphology of the GST layer and of the overlying cap layers. In particular, an improvement of about 15% has been observed in the GST bottom coverage with respect to different techniques. The process is also more reproducible.

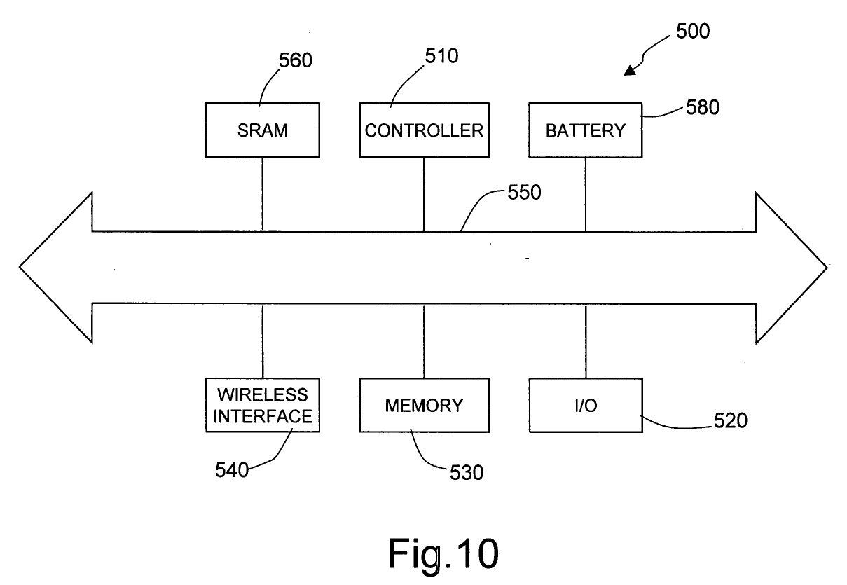

Turning to FIG. 10, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 includes a controller 510, an input/output (I/O) device 520 (e.g., a keypad, display), a memory 530, a wireless interface 540, and a static random access memory (SRAM) 560, coupled to each other via a bus 550. A battery 580 may supply power to the system 500.

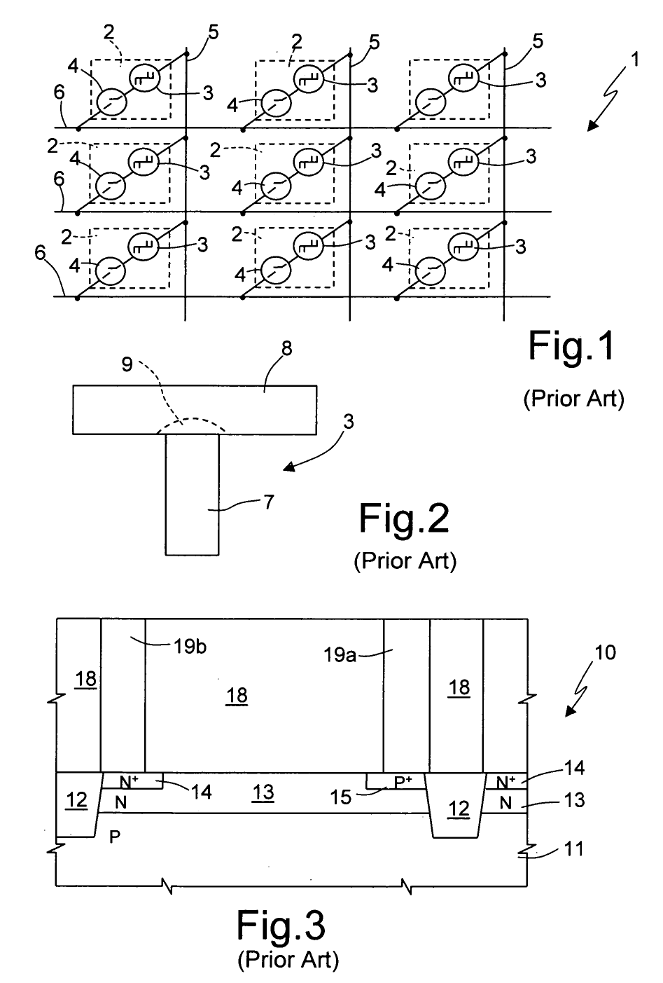

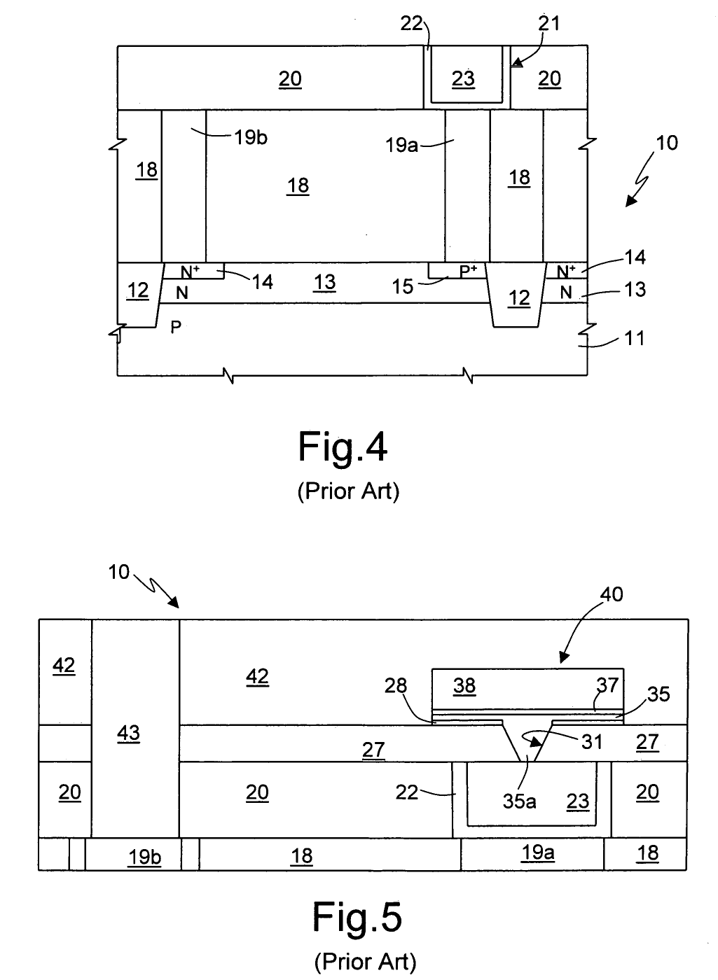

Controller 510 comprises, for example, one or more microprocessors, digital signal processors, micro-controllers, or the like. Memory 530 may be used to store messages transmitted to or by system 500. Memory 530 may also optionally be used to store instructions that are executed by controller 510 during the operation of system 500, and may be used to store user data. Memory 530 comprises a memory array as shown in FIG. 1.

The I/O device 520 is used to generate a message. The system 500 uses the wireless interface 540 to transmit and receive messages to and from a wireless communication network with a radio frequency (RF) signal. Examples of the wireless interface 540 include an antenna, or a wireless transceiver.

Finally, it is clear that numerous variations and modifications may be made to the method and chamber described and illustrated herein, all falling within the scope of the invention as defined in the attached claims. In particular, it is stressed that the present invention is not limited to GST, but applies to any chalcogenic material. Analogously, the invention is not limited to the specific type of phase change memory elements as disclosed.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

1. A method for depositing a chalcogenide layer in a phase change memory comprising:
providing a wafer in a deposition chamber;
depositing by pulsed sputtering, through a collimator, the chalcogenide layer by physical vapor deposition on the wafer in the deposition chamber.

2. The method according to claim 1 further comprising placing the collimator between a sputter target and the wafer, the collimator having a plurality of holes.

3. The method according to claim 1 wherein said chalcogenide layer is a GST layer.

4. The method according to claim 1, comprising, before depositing, forming a mold layer having an aperture on a surface of the wafer, wherein depositing comprises conformally depositing said chalcogenide layer on said surface and in said aperture.

5. The method according to claim 4, for manufacturing a phase change memory cell, including, before forming the mold layer, forming a resistive heater element in a dielectric layer, said resistive heater element extending below said aperture thereby said resistive heater element and in electrical contact with a portion of said chalcogenide layer in said aperture, said portion defining a phase change region; the process further comprising defining said chalcogenide layer; forming a select element in electrical contact with said phase change portion; and forming connection lines in electrical contact with said phase change region and said select element.

6. The method according to claim 2 wherein the step of depositing the chalcogenide layer comprises applying a DC sputtering voltage to the sputter target and periodically reversing said DC sputtering voltage.

7. The method according to claim 6 wherein said DC sputtering voltage is between 200 and 600 volts and is reversed with a frequency between 20 and 100 KHz.

8. A physical vapor deposition chamber comprising:
a wall surrounding a deposition area and said deposition area being closed by a cover;
a holder for a wafer extending in said deposition area;
a collimator in said deposition area between said cover and said holder; and
a sputter target over the collimator, said sputter target being connected to a DC pulsing power supply.

9. The physical vapor deposition chamber of claim 8 wherein the collimator comprises a plurality of holes.

10. The physical vapor deposition chamber of claim 8 wherein a distance between the sputter target and the collimator is adjustable.

11. The physical vapor deposition chamber of claim 8 wherein the sputter target causes pulsed sputtering of a chalcogenide layer.

12. A system, comprising:
a processor;
a static random access memory coupled to said processor; and
a phase change memory coupled to said processor, said phase change memory having a collimated layer of a chalcogenide material.

13. The system of claim 12, further comprising:
an interface coupled to said processor, said interface being a wireless interface.

14. A method comprising:
forming an aperture in a wafer, the aperture having a bottom, walls and an opening; and
depositing by pulsed sputtering, a collimated stream of ions of a chalcogenide material that conformally cover the surface of the wafer, the bottom of the aperture, and the walls of the aperture.

15. The method of claim 14 wherein the depositing comprises alternatingly applying a first voltage to sputter the ions of chalcogenide material, and applying a second reverse voltage to stop sputtering.

16. The method of claim 15 wherein the second voltage is substantially lower than the first voltage.

17. The method of claim 14 further comprising directing ions through a collimator having a plurality of holes.

18. The method of claim 14 wherein the collimated stream of ions travel perpendicularly to the surface of the wafer.

19. The method of claim 14 wherein the chalcogenide material is deposited in a layer of at least 120 nm thick on the surface of the wafer.

20. The method of claim 14 further comprising forming a resistive element in electrical contact with the chalcogenide material in the aperture.

21. The method of claim 14 further comprising:
forming a heater on a substrate;
forming a mold layer on the heater, the mold layer including the aperture above a portion of the heater; and
depositing a chalcogenic material through a collimator and into the aperture, the deposited chalcogenic material contacting the portion of the heater under the aperture.
